(19) United States
(12) Patent Application Publication
(10) Pub. No.: US 2008/0111607 A1
(43) Pub. Date: May 15, 2008

(54) AMPLITUDE-LINEAR DIFFERENTIAL PHASE SHIFT CIRCUIT

(76) Inventor: Robert T. Hart, Eatonton, GA (US)

Correspondence Address: BRYAN W. BOCKHOP, ESQ.;BOCKHOP & ASSOCIATES, LLC, 2375 MOSSY BRANCH DR., SNELLVILLE, GA, 30078, US

(21) Appl. No.: 11/558,522

(22) Filed: Nov. 10, 2006

(51) Int. Cl. H03H 11/16; H03K 3/00

(52) U.S. Cl. 327/255; 327/231

(57) ABSTRACT

A broad frequency range phase shift circuit is responsive to a radio-frequency signal generated by a radio-frequency source and generates a lagging phase signal and a leading phase signal, 90° out of phase with the lagging phase signal, corresponding to the radio-frequency signal. An operational amplifier has a signal input that receives the radio-frequency signal from the radio-frequency source and generates a low impedance amplified output signal. A series resonant circuit receives the amplified signal from the operational amplifier and shifts the phase of the amplified signal in an amount that approaches 90° as the amplified signal frequency approaches DC to 0° as the amplified signal frequency increases to the cut-off frequency. A transmission line receives the amplified signal from the operational amplifier and has an electrical length substantially equal to one-fourth of a wavelength corresponding to the cut-off frequency.

### BACKGROUND OF THE INVENTION

1. Field of the Invention

The present invention relates to radio-frequency circuits and, more specifically to circuits used in association with an antenna.

2. Description of the Prior Art

Radio signals usually start with electrical signals that have been modulated onto a radio frequency carrier wave. The resulting radio signal is transmitted using an antenna. The antenna is a system that generates an electrical field (E field) and a magnetic field (H field) that vary in correspondence with the radio signal, thereby forming radio frequency radiation. At a distance from the antenna, as a result of transmission effects of the medium through which the radio frequency radiation is being transmitted, the E field and the H field fall into phase with each other, thereby generating a Poynting vector, which is given by S=E×H, where S is the Poynting vector, E is the E field vector and H is the H field vector.

Conventional Hertz antenna systems are resonant systems that take the form of wire dipoles or ground plane antennas that run electrically in parallel to the output circuitry of radio frequency transmitters and receivers. Such antenna systems require, for maximum performance, that the length of each wire of the dipole, or the radiator of the ground plane (also referred to as the “counterpoise”), be one fourth of the wavelength of the radiation being transmitted or received. For example, if the wavelength of the radiation is 1000 ft., the length of the wire must be 250 ft. Thus, the typical wire antenna requires a substantial amount of space as a function of the wavelength being transmitted and received.

One type of antenna, referred to as an “EH antenna,” disclosed in U.S. Pat. Nos. 6,486,846; 6,864,849; and 6,956,535—each of which is incorporated herein by reference, develops an H-field and an E-field corresponding to a radio frequency power signal that are nominally in phase with each other. Because of this, an EH antenna is a compact antenna and may be used in situations in which a counterpoise is impractical. In certain situations, an EH antenna gives superior performance relative to a conventional antenna because it does not require substantial resistive loading. A conventional antenna requires resistive loading to have wide bandwidth. Thus, a conventional antenna trades efficiency for bandwidth. Also, a typical hand-held or portable radio does not form a good counter poise, which reduces radiation efficiency. An EH antenna, on the other hand, acts as a miniature dipole and, therefore, needs no counterpoise.

Typical existing EH antennas work well at VHF and UHF frequencies, but at HF (2-30 MHz) an EH Antenna may have limited bandwidth. A typical EH antenna includes a phasing and matching network that aligns the phase the E-field to that of the H-field. A phase shift of 90° is maintained between the E-field component and the H-field component of a signal. However, current designs of the phasing and matching network are designed to work for a narrow frequency bandwidth.

Therefore, there is a need for a phase shift circuit that maintains a constant phase shift between two parts of a radio-frequency signal over a range of frequencies.

There is also a need for a combiner circuit that combines two parts of a phase-shifted radio-frequency signal over a range of frequencies.

### SUMMARY OF THE INVENTION

The disadvantages of the prior art are overcome by the present invention which, in one aspect, is a phase shift circuit, responsive to a radio-frequency signal generated by a radio-frequency source, for generating a lagging phase signal corresponding to the radio-frequency signal and a leading phase signal corresponding to the radio-frequency signal. The leading phase signal is 90° out of phase with the lagging phase signal. The radio-frequency signal has a frequency between DC and a preselected cut-off frequency. An operational amplifier has a signal input that receives the radio-frequency signal from the radio-frequency source and generates a low impedance amplified output signal. A series resonant circuit receives the amplified signal from the operational amplifier and shifts the phase of the amplified signal in an amount that approaches 90° as the amplified signal frequency approaches DC to 0° as the amplified signal frequency increases to the cut-off frequency. A transmission line receives the amplified signal from the operational amplifier and has an electrical length substantially equal to one-fourth of a wavelength corresponding to the cut-off frequency.

In another aspect, the invention is an amplitude-linear differential phase shift circuit that is responsive to a radio-frequency signal. An operational amplifier is responsive to the radio-frequency signal and generates an amplified signal that has a predetermined gain. A leading phase shift circuit generates a leading phase signal corresponding to the amplified signal so that the leading phase signal leads the radio-frequency signal by 90° when the radio-frequency signal has a frequency that approaches DC and decreases linearly to 0° when the radio-frequency signal has a frequency equal to the predetermined cut-off frequency. A lagging phase shift circuit generates a lagging phase signal corresponding to the amplified signal so that the lagging phase signal lags the radio-frequency signal by an amount that approaches 0° when the radio-frequency signal has a frequency that approaches DC and that increases linearly to 90° when the radio-frequency signal has a frequency equal to a predetermined cut-off frequency. A constant phase difference of 90° is maintained between the lagging phase signal and the leading phase signal.

In another aspect, the invention is a linear vector addition diversity combiner circuit, for combining a first radio-frequency signal and a second radio-frequency signal. A leading phase shift circuit generates a leading phase signal corresponding to the second radio-frequency signal so that the leading phase signal leads the second radio-frequency signal by an amount that approaches 0° when the second radio-frequency signal has a frequency that approaches DC and increases linearly up to 90° when the second radio-frequency signal has a frequency equal to the predetermined cut-off frequency. The leading phase signal is coupled to the first node. A lagging phase shift circuit generates a lagging phase signal corresponding to the first radio-frequency signal so that the lagging phase signal lags the first radio-frequency signal by an amount that approaches 90° when the radio-frequency signal has a frequency that approaches DC and decreases linearly down to 0° when the radio-frequency signal has a frequency equal to a predetermined cut-off frequency. The lagging phase signal coupled to a first node. An operational amplifier is responsive to the first node and generates a combined signal that includes components of both the lagging phase signal and the leading phase signal.

In another aspect, the invention is a method of generating a pair of signals, each corresponding to a radio-frequency signal. A leading phase signal corresponding to the radio-frequency signal is generated so that the leading phase signal leads the radio-frequency signal by an amount that approaches 90° when the radio-frequency signal has a frequency that approaches DC and decreases linearly to 0° when the radio-frequency signal has a frequency equal to the predetermined cut-off frequency. A lagging phase signal corresponding to the radio-frequency signal is generated so that the lagging phase signal lags the radio-frequency signal by an amount that approaches 0° when the radio-frequency signal has a frequency that approaches DC and increases linearly to 90° when the radio-frequency signal has a frequency equal to a predetermined cut-off frequency. A constant phase difference of 90° is maintained between the lagging phase signal and the leading phase signal.

In yet another aspect, the invention is a method of combining a first radio-frequency signal with a second radio-frequency signal. A leading phase signal corresponding to the second radio-frequency signal is generated so that the leading phase signal leads the second radio-frequency signal by an amount that approaches 90° when the radio-frequency signal has a frequency that approaches DC and decreases linearly to 0° when the radio-frequency signal has a frequency equal to the predetermined cut-off frequency. A lagging phase signal corresponding to the first radio-frequency signal is generated so that the lagging phase signal lags the first radio-frequency signal by an amount that approaches 0° when the radio-frequency signal has a frequency that approaches DC and increases linearly to 90° when the radio-frequency signal has a frequency equal to a predetermined cut-off frequency. The lagging phase signal and the leading phase signal are fed into an input of an operational amplifier, thereby generating a vector-combined signal that includes components of both the lagging phase signal and the leading phase signal.

These and other aspects of the invention will become apparent from the following description of the preferred embodiments taken in conjunction with the following drawings. As would be obvious to one skilled in the art, many variations and modifications of the invention may be effected without departing from the spirit and scope of the novel concepts of the disclosure.

### BRIEF DESCRIPTION OF THE FIGURES OF THE DRAWINGS

FIG. 1A is a schematic diagram of a first representative embodiment of a phase shift circuit.

FIG. 1B is a graph showing relative phase shifts.

FIG. 2A is a schematic diagram of a second representative embodiment of a phase shift circuit.

FIG. 2B is a vector diagram showing a resulting vector combination of two signals.

### DETAILED DESCRIPTION OF THE INVENTION

A preferred embodiment of the invention is now described in detail. Referring to the drawings, like numbers indicate like parts throughout the views. As used in the description herein and throughout the claims, the following terms take the meanings explicitly associated herein, unless the context clearly dictates otherwise: the meaning of “a,” “an,” and “the” includes plural reference, the meaning of “in” includes “in” and “on.”

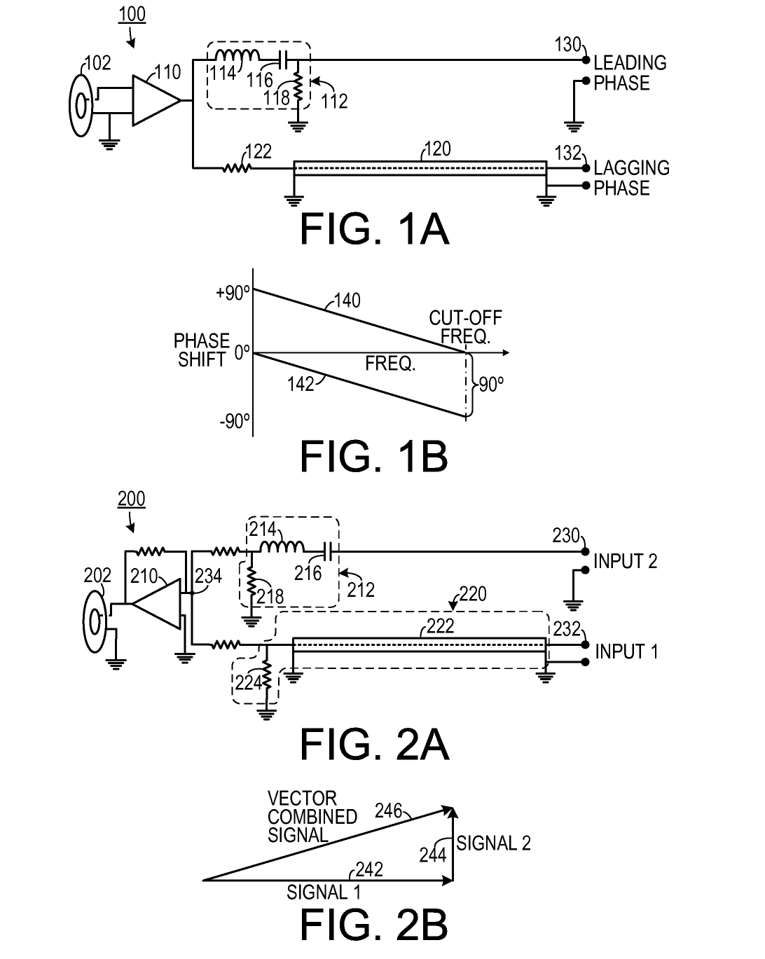

As shown in FIG. 1A, one embodiment is a phase shift circuit 100 that generates a leading phase signal 130 and a lagging phase signal 132 that both correspond to a radio-frequency signal having a frequency between DC and a preselected cut-off frequency. The radio-frequency signal is generated by a radio-frequency source 102. The leading phase signal 130 is 90° out of phase with the lagging phase signal 132.

An operational amplifier 110 has a signal input that receives the radio-frequency signal from the radio-frequency source 102 and generates a low impedance amplified output signal. A series resonant circuit 112 receives the amplified signal from the operational amplifier 110 and shifts the phase of the amplified signal in an amount that approaches 90° as the amplified signal frequency approaches DC to 0° as the amplified signal frequency increases to the cut-off frequency. The series resonant circuit 112 could include, for example, an inductor 114 in series with a capacitor 116 that is coupled to ground through a resistor 118. Preferably, the components of the series resonant circuit 112 will be chosen so that the Q of the series resonant circuit 112 will have a nominal value of 0.707 relative to the terminating resistor.

A transmission line 120 receives the amplified signal from the operational amplifier and has an electrical length substantially equal to one-fourth of a wavelength corresponding to the cut-off frequency. The transmission line 120 could be a coaxial cable, in one example, a twisted pair, a wave guide, or any other type of transmission line suitable for the frequency of the signal. The transmission line 120 would typically be coupled to the operational amplifier 110 through an impedance-matching resistor 122.

As shown in FIG. 1B, the phase shift 140 of the leading phase signal 130 will approach 90° when the frequency of the radio-frequency signal approaches DC. However, the phase shift 140 will decrease linearly to 0° as the frequency of the radio-frequency signal approaches the cut-off frequency. Similarly, the phase shift 142 of the lagging phase signal 132 will approach 0° when the frequency of the radio-frequency signal approaches DC and will decrease linearly to −90° as the frequency of the radio-frequency signal approaches the cut-off frequency. Thus, there is always a 90° phase shift between the leading phase signal 130 and the lagging phase signal 132 for frequencies between DC and the cut-off frequency.

To receive a two component signal, such as a signal that includes a first input signal and a second input signal, a linear vector addition diversity combiner circuit is employed. As shown in FIG. 2A, a linear vector addition diversity combiner circuit 200 for combining a first radio-frequency signal 232 and a second radio-frequency signal 230 includes a leading phase shift circuit 212 and a lagging phase shift circuit 220.

The leading phase shift circuit 212 receives a second input signal 230 and, depending of the frequency of the second radio-frequency signal 230, shifts the phase of the second radio-frequency signal 230 by a predetermined amount. Once shifted, the signal is coupled to an operational amplifier 210, which then delivers a combined signal 202 to a receiver. The leading phase shift circuit 212 generates a leading phase signal corresponding to the second radio-frequency signal so that the leading phase signal leads the second radio-frequency signal 230 by an amount that approaches 90° when the second radio-frequency signal has a frequency that approaches DC and increases linearly up to 0° when the second radio-frequency signal has a frequency equal to the predetermined cut-off frequency. In one embodiment, the leading phase shift circuit 212 includes a capacitor 216 that is coupled to the second radio-frequency signal 230 and that is coupled to an inductor 214. (The order of placement of the inductor 214 and the capacitor 216 may not be critical.) The inductor 214 and a terminating resistor 218 are coupled to a first node 234, which is coupled to the operational amplifier 210. Typically, the components of the leading phase shift circuit 212 will be selected so that the leading phase shift circuit 212 will have a preselected Q that has a nominal value of 0.707 relative to the terminating resistor 218 at the cutoff frequency.

A lagging phase shift circuit 222 generates a lagging phase signal corresponding to the first radio-frequency signal 232. The lagging phase signal lags the first radio-frequency signal 232 by an amount that approaches 0° when the radio-frequency signal has a frequency that approaches DC and decreases linearly down to 90° when the radio-frequency signal has a frequency equal to a predetermined cut-off frequency. The lagging phase signal is coupled to the operational amplifier 210 through a first node 234. The lagging phase shift circuit 222 can include a transmission line, such as a coaxial cable having an electrical length that is one-fourth of the wavelength corresponding to the cut-off frequency. The transmission line 222 is terminated with a resistor 224.

The operational amplifier 210 is responsive to the first node 234 and generates a combined signal that includes components of both the lagging phase signal and the leading phase signal. As shown in FIG. 2B, the signal 244 from the leading phase shift circuit 212 and the signal 246 from the lagging phase shift circuit 222 are vector combined to create a vector combined signal 246 by the operational amplifier 210, which is then received by the receiver 202.

The above described embodiments, while including the preferred embodiment and the best mode of the invention known to the inventor at the time of filing, are given as illustrative examples only. It will be readily appreciated that many deviations may be made from the specific embodiments disclosed in this specification without departing from the spirit and scope of the invention. Accordingly, the scope of the invention is to be determined by the claims below rather than being limited to the specifically described embodiments above.

What is claimed is:

1. A phase shift circuit, responsive to a radio-frequency signal generated by a radio-frequency source, for generating a lagging phase signal corresponding to the radio-frequency signal and a leading phase signal corresponding to the radio-frequency signal that is 90° out of phase with the lagging phase signal, the radio-frequency signal having a frequency between DC and a preselected cut-off frequency, the phase shift circuit comprising:
a. an operational amplifier having a signal input that receives the radio-frequency signal from the radio-frequency source and that generates a low impedance amplified output signal;
b. a series resonant circuit that receives the amplified signal from the operational amplifier and that shifts the phase of the amplified signal in an amount that approaches 90° as the amplified signal frequency approaches DC to 0° as the amplified signal frequency increases to the cut-off frequency; and
c. a transmission line that receives the amplified signal from the operational amplifier and that has an electrical length substantially equal to one-fourth of a wavelength corresponding to the cut-off frequency.

2. The phase shift circuit of claim 1, wherein the transmission line comprises a coaxial cable.

3. The phase shift circuit of claim 1, further comprising a resistor, having an impedance that matches the transmission line, that is in series between the amplified signal and the transmission line.

4. The phase shift circuit of claim 1, wherein the series resonant circuit includes an inductor that is coupled to the amplified signal and a capacitor that is in series with the inductor, and a terminating resistor, the inductor and the capacitor chosen so that the series resonant circuit elements have a preselected Q relative to the terminating resistor.

5. The phase shift circuit of claim 4, wherein the preselected Q has a nominal value of 0.707.

6. An amplitude-linear differential phase shift circuit that is responsive to a radio-frequency signal, comprising:
a. an operational amplifier responsive to the radio-frequency signal that generates an amplified signal having a predetermined gain;
b. a leading phase shift circuit that generates a leading phase signal corresponding to the amplified signal so that the leading phase signal leads the radio-frequency signal by 90° when the radio-frequency signal has a frequency that approaches DC and decreases linearly to 0° when the radio-frequency signal has a frequency equal to the predetermined cut-off frequency; and
c. a lagging phase shift circuit that generates a lagging phase signal corresponding to the amplified signal so that the lagging phase signal lags the radio-frequency signal by an amount that approaches 0° when the radio-frequency signal has a frequency that approaches DC and that increases linearly to 90° when the radio-frequency signal has a frequency equal to a predetermined cut-off frequency,
so that a constant phase difference of 90° is maintained between the lagging phase signal and the leading phase signal.

7. The amplitude-linear differential phase shift circuit of claim 6, wherein the lagging phase shift circuit comprises a transmission line.

8. The amplitude-linear differential phase shift circuit of claim 7, wherein the transmission line has an electrical length equal to one quarter of a wavelength corresponding to the cut-off frequency.

9. The amplitude-linear differential phase shift circuit of claim 7, wherein the transmission line comprises a coaxial cable.

10. The amplitude-linear differential phase shift circuit of claim 6, wherein the leading phase shift circuit comprises an inductor that is coupled to the amplified signal and a capacitor that is in series with the inductor, the inductor and the capacitor chosen so that the series resonant circuit has a preselected Q at the cut-off frequency.

11. The amplitude-linear differential phase shift circuit of claim 10, wherein the preselected Q has a nominal value of 0.707.

12. A linear vector addition diversity combiner circuit, for combining a first radio-frequency signal and a second radio-frequency signal, comprising:
a. a leading phase shift circuit that generates a leading phase signal corresponding to the second radio-frequency signal so that the leading phase signal leads the second radio-frequency signal by an amount that approaches 90° when the second radio-frequency signal has a frequency that approaches DC and increases linearly to 0° when the second radio-frequency signal has a frequency equal to the predetermined cut-off frequency, the leading phase signal coupled to the first node;
b. a lagging phase shift circuit that generates a lagging phase signal corresponding to the first radio-frequency signal so that the lagging phase signal lags the first radio-frequency signal by an amount that approaches 0° when the radio-frequency signal has a frequency that approaches DC and increases linearly to 90° when the radio-frequency signal has a frequency equal to a predetermined cut-off frequency, the lagging phase signal coupled to a first node; and
c. an operational amplifier responsive to the first node that generates a combined signal that includes components of both the lagging phase signal and the leading phase signal.

13. The linear vector addition diversity combiner circuit of claim 12, wherein the lagging phase shift circuit comprises a transmission line.

14. The linear vector addition diversity combiner circuit of claim 13, wherein the transmission line has an electrical length equal to one quarter of a wavelength corresponding to the cut-off frequency.

15. The linear vector addition diversity combiner circuit of claim 13, wherein the transmission line comprises a coaxial cable.

16. The linear vector addition diversity combiner circuit of claim 12, wherein the leading phase shift circuit comprises an inductor and a capacitor that are coupled to the amplified signal and a terminating resistor, the inductor and the capacitor having a preselected Q relative to the terminating resistor at the cut-off frequency.

17. The linear vector addition diversity combiner circuit of claim 16, wherein the preselected Q has a nominal value of 0.707.

18. A method of generating a pair of signals, each corresponding to a radio-frequency signal, comprising the steps of:
a. generating a leading phase signal corresponding to the radio-frequency signal so that the leading phase signal leads the radio-frequency signal by an amount that approaches 90° when the radio-frequency signal has a frequency that approaches DC and decreases linearly to 0° when the radio-frequency signal has a frequency equal to the predetermined cut-off frequency; and
b. generating a lagging phase signal corresponding to the radio-frequency signal so that the lagging phase signal lags the radio-frequency signal by an amount that approaches 0° when the radio-frequency signal has a frequency that approaches DC and increases linearly to 90° when the radio-frequency signal has a frequency equal to a predetermined cut-off frequency,
so that a constant phase difference of 90° is maintained between the lagging phase signal and the leading phase signal.

19. The method of claim 18, further comprising the step of feeding the radio-frequency signal into an operational amplifier, thereby generating an amplified signal, prior to the steps of generating a lagging phase signal and generating a leading phase signal.

20. The method of claim 19, wherein the step of generating a lagging phase signal comprises the step of feeding the amplified signal into a transmission line having an electrical length equal to one quarter of a wavelength corresponding to the cut-off frequency.

21. The method of claim 19, wherein the step of generating a leading phase signal comprises the step of feeding the amplified signal into a leading phase shift circuit that includes an inductor and a capacitor that is in series with the inductor that are coupled to the amplified signal, and a terminating resistor, the inductor and the capacitor having a preselected Q with a nominal value of 0.707, relative to the terminating resistor, at the cut-off frequency.

22. A method of combining a first radio-frequency signal with a second radio-frequency signal, comprising the steps of:
a. generating a leading phase signal corresponding to the second radio-frequency signal so that the leading phase signal leads the second radio-frequency signal by an amount that approaches 90° when the radio-frequency signal has a frequency that approaches DC and decreases linearly to 0° when the radio-frequency signal has a frequency equal to the predetermined cut-off frequency;
b. generating a lagging phase signal corresponding to the first radio-frequency signal so that the lagging phase signal lags the first radio-frequency signal by an amount that approaches 0° when the radio-frequency signal has a frequency that approaches DC and increases linearly to 90° when the radio-frequency signal has a frequency equal to a predetermined cut-off frequency; and
c. feeding the lagging phase signal and the leading phase signal into an input of an operational amplifier, thereby generating a vector-combined signal that includes components of both the lagging phase signal and the leading phase signal.

23. The method of claim 22, wherein the step of generating a lagging phase signal comprises the step of feeding the first radio-frequency signal into a transmission line having an electrical length equal to one quarter of a wavelength corresponding to the cut-off frequency.

24. The method of claim 22, wherein the step of generating a leading phase signal comprises the step of feeding the second radio-frequency signal into a leading phase shift series resonant circuit that includes an inductor, a capacitor and a terminating resistor, the inductor and the capacitor chosen to have a Q with a nominal value of 0.707 relative to the terminating resistor at the cut-off frequency.
